(19) United States
(12) Patent Application Publication
(10) Pub. No.: US 2019/0176727 A1
(43) Pub. Date: Jun. 13, 2019

(54) PORTABLE POWER SOURCE WITH REMOVABLE BATTERY PACK

(71) Applicant: Newfrey LLC, New Britain, CT (US)

(72) Inventors: Joseph HALUSKA, Sagamore Hills, OH (US); William WHALE, Berkley, MI (US); Hung TRAN, North Olmsted, OH (US); Craig MONTROSS, Hartville, OH (US)

(73) Assignee: Newfrey LLC, New Britain, CT (US)

(21) Appl. No.: 15/834,936

(22) Filed: Dec. 7, 2017

(51) Int. Cl. B60R 16/033; H02J 7/00; H02M 3/158; B60R 16/04; G01R 31/36

(52) U.S. Cl. CPC B60R 16/033; H02J 7/0063; H02M 3/1582; H02M 1/00; G01R 31/362; G01R 31/3665; H02J 2007/0067; B60R 16/04

(57) ABSTRACT

A portable power source can be used during the assembly of a vehicle. The portable power source includes a housing with a docking port and a rechargeable battery pack removably received in the docking port. The rechargeable battery pack is configured to provide electrical power for programming one or more electrical control systems of the vehicle. The example portable power source also includes a pair of cables connected to the housing and electrically coupled to the rechargeable battery pack. The pair of cables are configured to removably connect to battery leads of the vehicle.

### FIELD

The present disclosure relates to a portable power source with a removable battery pack and related methods of use.

### BACKGROUND

This section provides background information related to the present disclosure which is not necessarily prior art.

Modern vehicles often include one or more electrical control systems that enable the complex functionality of the vehicle. Such electrical control systems can include an engine control system, a transmission control system, a brake control system, a body control system, a suspension control system, a telematics control system, a climate control system, a safety control system and the like. The electrical control systems can be installed into a vehicle during the assembly process. The software, settings, parameters and/or control algorithms associated with the electrical control systems can be programmed into the electrical control systems during the assembly of the vehicle.

In order to program the software, settings, parameters and/or control algorithms into the electrical control systems, the electrical control systems need to have a sufficient power source to energize the electrical control systems during the programming process. Disadvantages exist in current systems and methods of providing sufficient power to the electrical control systems during the programming process. In some existing systems and methods, a vehicle's primary battery is used to program the electrical control systems of the vehicle. In such existing systems and methods, the use of the vehicle's primary battery is inflexible in that the programming process must be located in the vehicle assembly process after the vehicle's primary battery is installed. In addition, the vehicle's primary battery is partially discharged as a result of the programming process. Due to these disadvantages and others, there exists a need to provide a low-cost, reliable, power source to energize the electrical control systems of a vehicle during the assembly process.

### SUMMARY

This section provides a general summary of the disclosure, and is not a comprehensive disclosure of its full scope or all of its features.

In one example in accordance with the present disclosure, a portable power source can be used during the assembly of a vehicle. The example portable power source can include a housing with a docking port and a rechargeable battery pack removably received in the docking port. The rechargeable battery pack can be configured to provide electrical power for programming one or more electrical control systems of the vehicle. The example portable power source can also include a pair of cables connected to the housing and electrically coupled to the rechargeable battery pack. The pair of cables can be configured to removably connect to battery leads of the vehicle.

The example portable power source can further include a status indicator mounted on the housing that is configured to indicate an operating condition, a low-level charge condition and a fault condition. The example power source can also include a power source controller located inside the housing and electrically coupled to the rechargeable battery pack, the pair of cables and the status indicator. The power source controller, in one example, is configured to monitor a battery voltage of the rechargeable battery pack and monitor an output current being delivered to the pair of cables.

In one example method in accordance with the present disclosure, a method of powering a vehicle on an assembly line for programming one or more electrical control systems of the vehicle is contemplated. The example method may include connecting a portable power source to battery leads of the vehicle to electrically connect the power source to the one or more electrical control systems of the vehicle. The example method also may include determining, by the power source controller, if the battery voltage of the battery pack is greater than a first predetermined voltage threshold and interrupting the electrical connection of the power source to the one or more electrical control systems of the vehicle and causing the status indicator to indicate the low-level charge condition and the fault condition if the battery voltage is not greater than the first predetermined voltage threshold.

In another example in accordance with the present disclosure, a portable power source for powering one or more electrical control systems of a vehicle during programming thereof while the vehicle moves through multiple stages of an assembly line is provided. The portable power source comprises a housing sized to fit inside a battery tray of the vehicle. The housing includes a docking port for removably receiving a rechargeable battery pack therein. The power source also includes a pair of cables for electrically coupling the portable power source to battery leads of the vehicle and a switching voltage regulator controller electrically coupled to the pair of cables that is operable to transform battery power to output power for powering the one or more electrical control systems of the vehicle. The power source also includes a power source controller electrically coupled to the docking port and the switching voltage regulator. The power source controller is operable to activate or deactivate the voltage controller in response to sensor signals received from a plurality of battery connection points on the docking port.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an illustration of an example portable power source in accordance with present disclosure;

FIG. 2 is a block diagram of the example portable power source of FIG. 1;

FIG. 3 is a block diagram of an example power source controller that can be used in the power source of FIG. 1;

FIG. 4 is a circuit diagram of an example power source controller that can be used in the power source of FIG. 1;

FIG. 5 is a circuit diagram showing example connection circuits that can be used to connect the example power source controller of FIG. 4 to a battery pack, a battery pack voltage monitor and a battery temperature monitor;

FIG. 6 is a circuit diagram showing example circuits that include an example reverse polarity protector, a first regulator and a second regulator that can be used in the power source of FIG. 1;

FIG. 7 is a circuit diagram showing an example status indicator that can be used in the power source of FIG. 1;

FIG. 8A is a circuit diagram showing an example regulator activation circuit that can be used in the voltage regulator of the example power source of FIG. 1;

FIG. 8B is a circuit diagram showing an example regulator pairing circuit that can be used in the voltage regulator of the example power source of FIG. 1;

FIG. 8C is a circuit diagram showing an example first regulator circuit that can be used in the voltage regulator of the example power source of FIG. 1;

FIG. 8D is a circuit diagram showing an example second regulator circuit that can be used in the voltage regulator of the example power source of FIG. 1;

FIG. 8E is a circuit diagram showing an example third regulator circuit that can be used in the voltage regulator of the example power source of FIG. 1;

FIG. 8F is a magnified view of the regulator controller used in the example regulator circuits of FIGS. 8C, 8D and 8E;

FIG. 9 is circuit diagram showing example current sensors and a short circuit and over current protector that can be used in the example power source of FIG. 1;

FIG. 10 is circuit diagram showing an example fan connection circuit that can be used in the example power source of FIG. 1;

FIG. 11 is a circuit diagram showing an example output reverse polarity protection that can be used in the example power source of FIG. 1;

FIG. 12 is circuit diagram showing an example output voltage monitor that can be used in the example power source of FIG. 1;

FIG. 13 is a circuit diagram showing a first output circuit and a second output circuit that can be used in the example power source of FIG. 1;

FIGS. 14A and 14B are flow charts illustrating one example method of using the example power source of FIG. 1; and

FIG. 15 is another example method of using the example portable power source of FIG. 1.

Corresponding reference numerals indicate corresponding parts throughout the several views of the drawings.

### DETAILED DESCRIPTION

Example embodiments will now be described more fully with reference to the accompanying drawings.

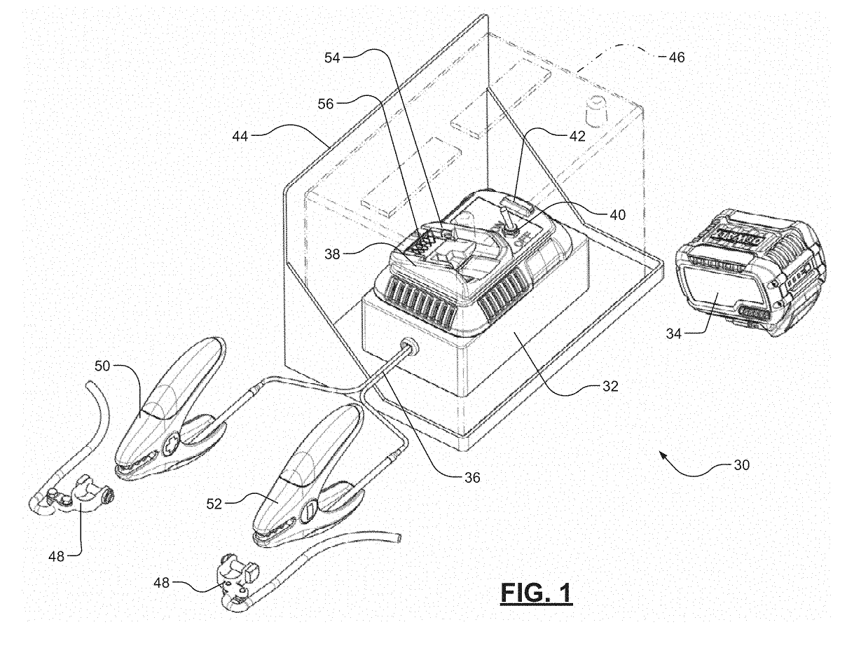

As shown in FIG. 1, one example portable power source 30 includes a housing 32, a battery pack 34, and a pair of cables 36. As shown, the power source 30 is portable such that it can be easily carried and transported by a user. In the example shown, the housing 32 is a rectangular enclosure that is used to enclose the various other components and electronic circuitry as will be described. The housing 32 can be sized so that it can be located in a battery tray 44 of a vehicle. As can be appreciated, the battery tray 44 defines a battery compartment and is sized to hold a typical automobile battery 46. The typical automobile battery 46 is an engine cranking battery in that it can be used to start the engine of the vehicle. The housing 32 has a smaller footprint than the battery 46 so that the power source 30 can reside in the battery tray 44 during the assembly of the vehicle and can be used to energize the electrical control systems of the vehicle before the battery 46 is installed in the vehicle. In other examples of the power source 30, the housing 32 can have other shapes and sizes so that the power source 30 can be integrated into the vehicle assembly process or into other testing and/or repair processes.

As further shown, the housing 32 includes a docking port 38, a switch 40 and a status indicator 42. The docking port 38 is connected at a top portion of the housing 32 and includes one or more rails 54 that are configured to receive and retain the battery pack 34 to the housing. The docking port 38 also includes one or more battery connection points 56 or a connection jack that electrically couples the battery pack 34 to the power source 30. As further described below, the docking port 38 can include multiple battery connection points 56 that correspond to a battery of the battery pack 34 that includes multiple battery terminals. The battery connection points 56 couple to the multiple battery terminals to electrically couple the housing 32 to the battery pack 34. The docking port 38 also permits the battery pack 34 to be removed from the housing 32 for charging, repair or replacement as desired.

In the example shown, the housing 32 includes one docking port 38. In other examples, the housing 32 can include two or more docking ports 38. It may be desirable, depending on the application and the electrical requirements thereof, to provide a power source 30 with two or more batteries or battery packs in the battery pack 34. In still other examples, the docking port 38 can be electrically coupled to the power source using a flexible cable. In such examples, the housing 32 can be separate from the docking port 38 and/or the housing 32 can include connectors that permit the docking port 38 to be removably connected to the housing 32 to customize the power source 30 to the various needs in differing applications.

The switch 40 is positioned adjacent to the docking port 38 on a top portion of the housing 32 in the example shown. In other embodiments, the switch 40 can be positioned in other locations but is preferably located in a position that is easily accessible by a user. The switch 40 permits a user to activate the power source 30. In this example, the switch 40 is a toggle switch. In other examples, other types of switches can be used including push buttons, slide switches, rotary switches and the like. In still other examples, the power source 30 can include a user input interface other than or in addition to a switch. In such other examples, the power source 30 can include a touch screen or a wireless interface that can be used in connection with the activation of the power source 30 or other functionality of the power source 30 as will be described.

The status indicator 42, in the example shown in FIG. 1, is a light panel positioned on a top portion of the housing 32. The status indicator 42, in this example, includes three LED lights. The status indicator 42 includes a green light, a yellow light and a red light. The status indicator 42 is used to display a condition of the power source 30 and/or a condition of the battery pack 34. For example and as will be further described below, the status indicator 42 is used to display an operating condition, a low-level charge condition and/or a fault condition. In other examples of the power source 30, the status indicator 42 can include more or less lights, other types of visual or auditory indicators or other indicators to indicate, to a user, the condition of the power source 30 and/or the condition of the battery pack 34. In one such alternate example, the status indicator can be a display screen that can display words, symbols or other indicators. The status indicator 42 can also be combined with the switch 40 on a touch screen, for example.

In examples of the power source 30 that include more than one battery pack 34, the status indicator 42 can include additional lights (or other additional indicators). Such additional lights can correspond to the additional battery packs 34. In one such alternate example, a second battery pack 34 is included in the power source 30. The status indicator 42, in such an example, can include a second series of lights. The second series of lights can be used to indicate the operating condition, the low-level charge condition and the fault condition of the second battery pack 34.

The pair of cables 36 or output terminals extend outward from the housing 32. The pair of cables 36, in this example, is a pair of electrical wires capable of transmitting the electrical power from the power source 30 to the vehicle. In the example shown, the pair of cables 36 includes a first wire that terminates at a positive connector 50 and a second wire that terminates at a negative connector 52. As can be appreciated, the positive connector 50 and the negative connector 52 are configured to removably connect to battery leads 48 of the vehicle. In the example shown, the positive connector 50 and the negative connector 52 are alligator-type clip connectors. The positive connector 50 and/or the negative connector 52 can be other types of electrical connectors as well. The positive connector 50 and the negative connector 52 can be used to connect the power source 30 at other locations or to other terminals in order to electrically couple the power source 30 at other locations or to other electrical systems.

As previously described, the docking port 38 is configured to receive the battery pack 34. The battery pack 34 can be a rechargeable lithium-ion battery pack, in one example. One such type of battery pack suitable for use with the power source 30 is a rechargeable battery pack used in cordless power tools or other cordless equipment. For example, a 20 volt, 9.0 Amp-hour power tool battery (or tool battery pack) can be used as the battery pack 34. In other examples, multiple 20 volt, 9.0 Amp-hour batteries (or battery packs) can be used as the battery pack 34. In other examples, a different suitable battery (or batteries) can be used as the battery pack 34.

One example battery pack 34 can include at least six battery terminals and the docking port 38 includes at least six corresponding battery connection points 56. The battery pack 34 can include one or more electrochemical cells. The battery pack 34 can also include one or more internal electrical circuits such as a temperature sensor (e.g. a thermistor) and/or a voltage sensor. The six battery terminals can be used to electrically couple the electrochemical cells, the temperature sensor, the voltage sensor and/or other internal battery circuits to the power source 30 through the battery connection points 56 on the docking port 38. The battery terminals can also be used to electrically couple the battery pack 34 to the housing 32 and/or to the pair of cables 36. In other examples, the docking port 38 can include a connection jack with the six battery terminals or a connection jack with more or less than six battery terminals. The battery connection points 56 and/or the connection jack electrically couples the battery pack 34 to the power source 30. As can be appreciated, if other battery packs 34 are used that have more or less than six battery terminals, the docking port 28 can include a corresponding quantity of battery connection points 56.

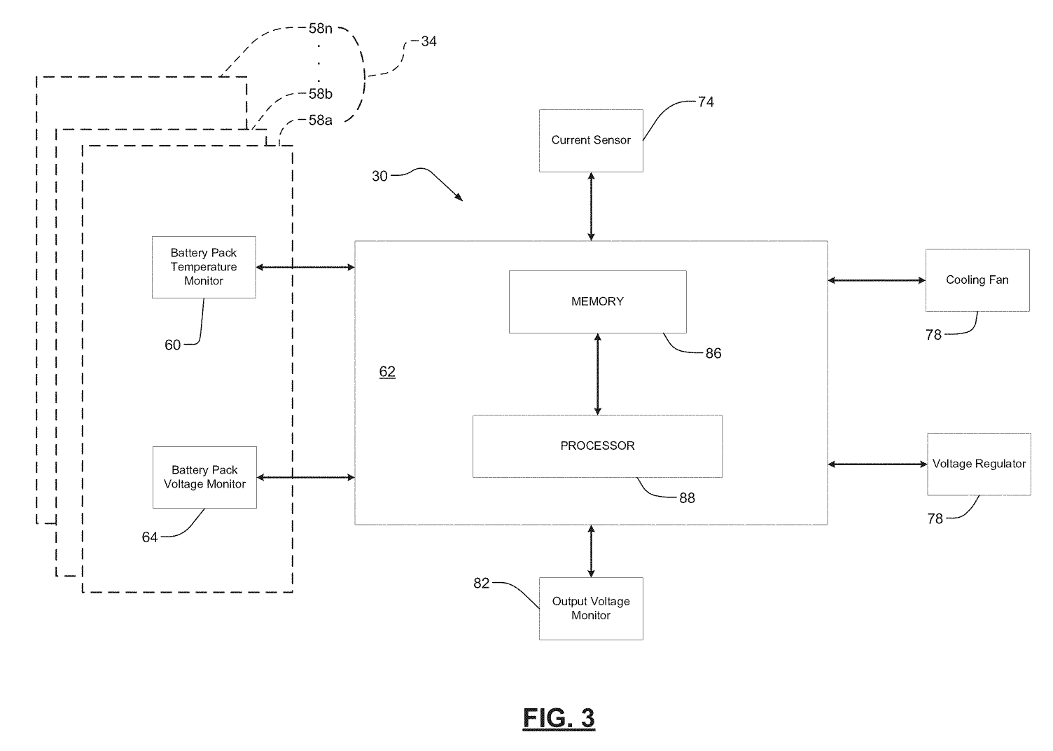

As shown in the example of FIG. 3, the controller 62 is coupled to the battery pack temperature monitor 60 and the battery pack voltage monitor 64. As shown, the battery pack temperature monitor 60 and/or the battery pack voltage monitor 64 can optionally be located inside an individual battery (or battery pack) 58 of the battery pack 34. In other examples, there can be multiple battery pack temperature monitors 60 and/or multiple battery pack voltage monitors 64 located inside each battery (or battery pack) 58 of a plurality of batteries (or a plurality of battery packs) 58a through 58n.

During the assembly process of the vehicle, the power source 30 can be used to energize one or more electrical control systems of the vehicle in order to program such electrical control systems. The process of programming the electrical control systems of the vehicle can take 30 minutes or more. It is important that the power source 30 delivers suitable output power to energize the one or more electrical systems of the vehicle during the programming process without interruption. If the output power is interrupted and/or the electrical control systems of the vehicle are de-energized during the programming process, the electrical control systems can be corrupted causing significant delays in the assembly process.

In this context, the battery pack 34 of the power source 30 can preferably deliver suitable output power to energize the electrical control systems of the vehicle without interruption during the entire programming process. In another example, the battery pack 34 of the power source 30 can deliver suitable output power to energize the electrical control systems of two vehicles without the need for recharging the battery pack 34. In still another example, the power source 30 includes two or more rechargeable tool battery packs that can permit the power source 30 to be used on a vehicle assembly line for an entire shift without the need for recharging the battery pack 34. As can be appreciated, it can be desirable to provide output power for multiple vehicle programming cycles to multiple vehicles during the assembly process using a single battery pack 34 without the need to recharge the battery pack 34 after each vehicle programming cycle.

In one example of the power source 30, the battery pack 34 has a sufficient capacity to deliver 12 volts at 7 Amps for at least 30 minutes. In another example, the battery pack 34 has sufficient capacity to deliver 12 volts at 7 Amps for at least 60 minutes. In still another example, the battery pack 34 has a sufficient capacity to deliver 12 volts at 7 Amps for at least 8 hours. In other examples, the battery pack 34 can have other capacities in order to deliver suitable output power as may be needed.

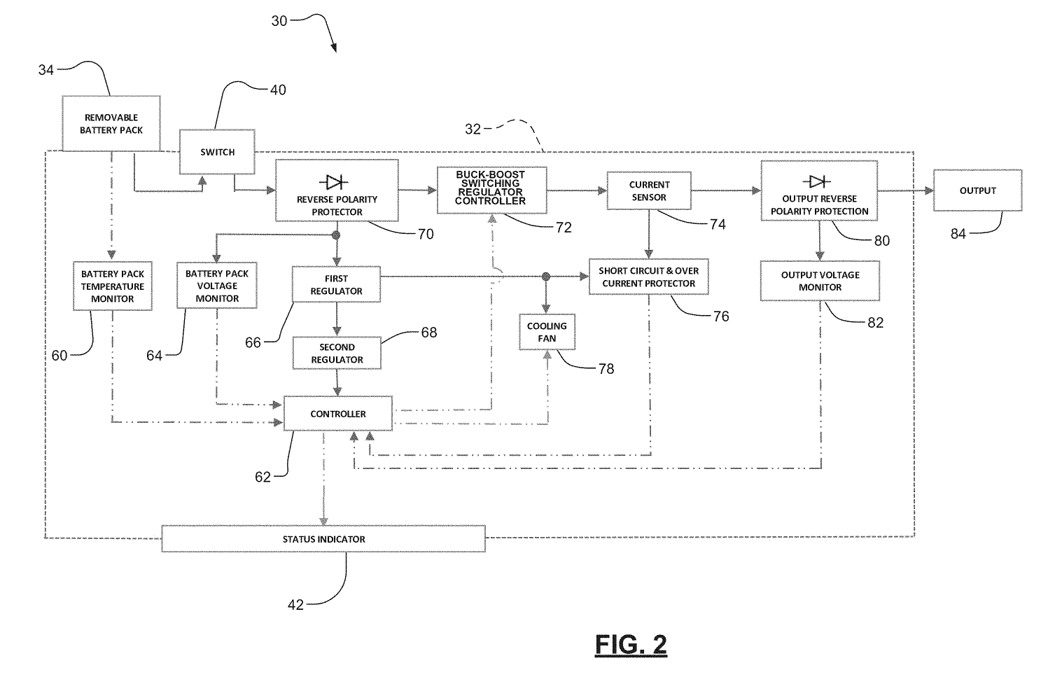

Referring now to FIG. 2, an example power source 30 is illustrated. As shown, the example power source 30 includes the removable battery pack 34, the switch 40 and the status indicator 42 mounted to the housing 32. The other components, as shown in FIG. 2, can be positioned inside the housing 32. As can be appreciated, one or more of the components shown inside the housing 32 can be mounted on the housing 32 or the housing 32 can be separated into one or more separate modular housings (not shown) that can be electrically coupled to one another to deliver the same or similar functionality as described.

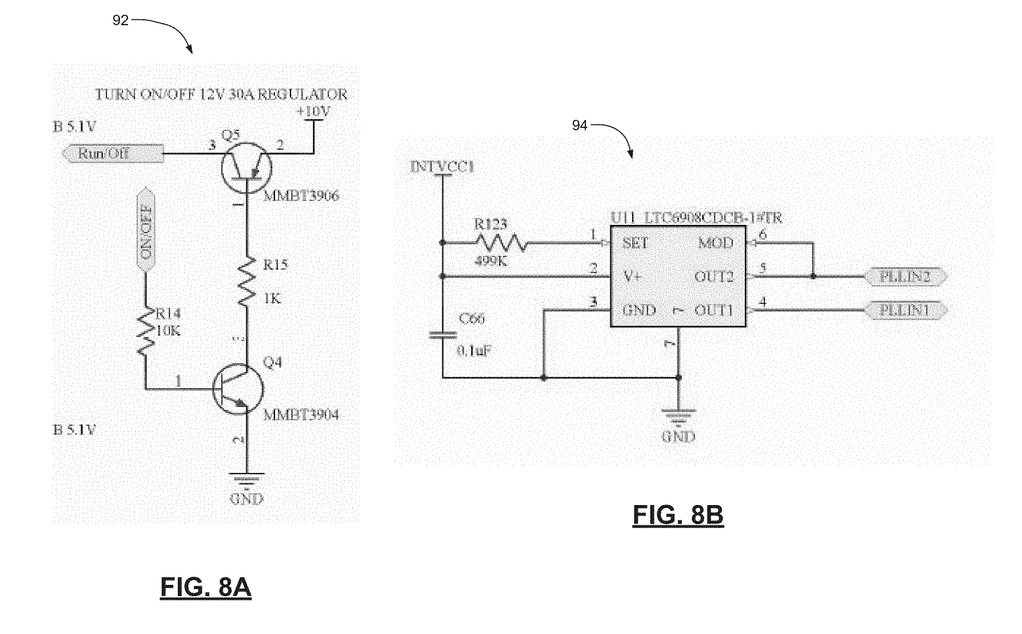

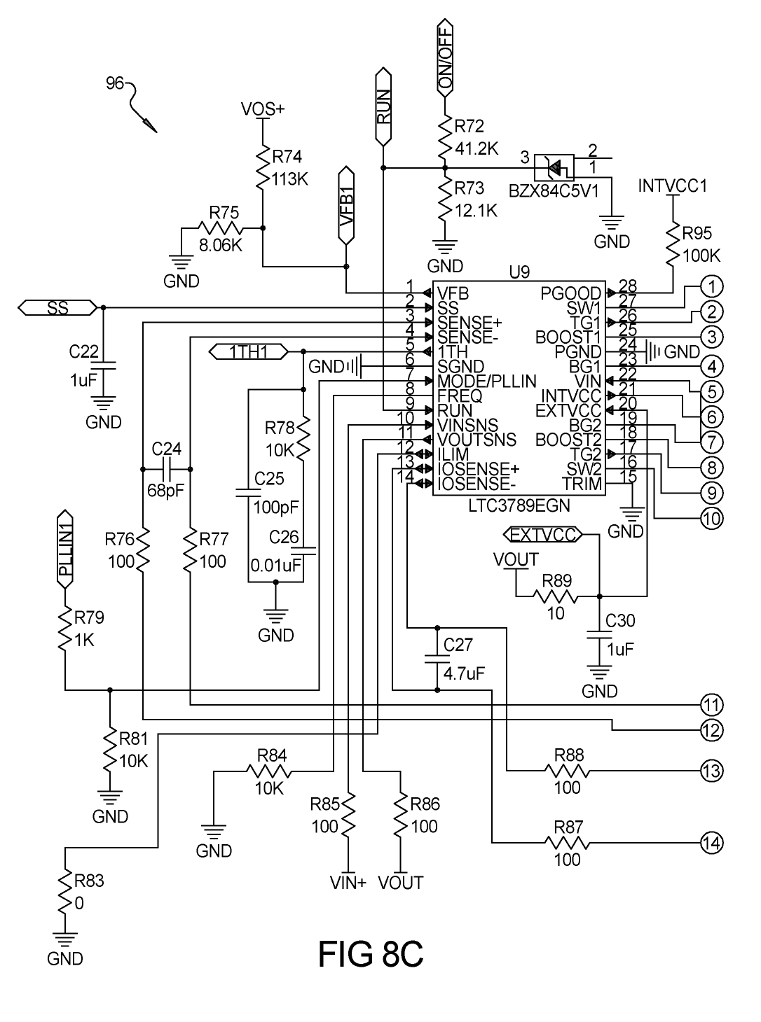

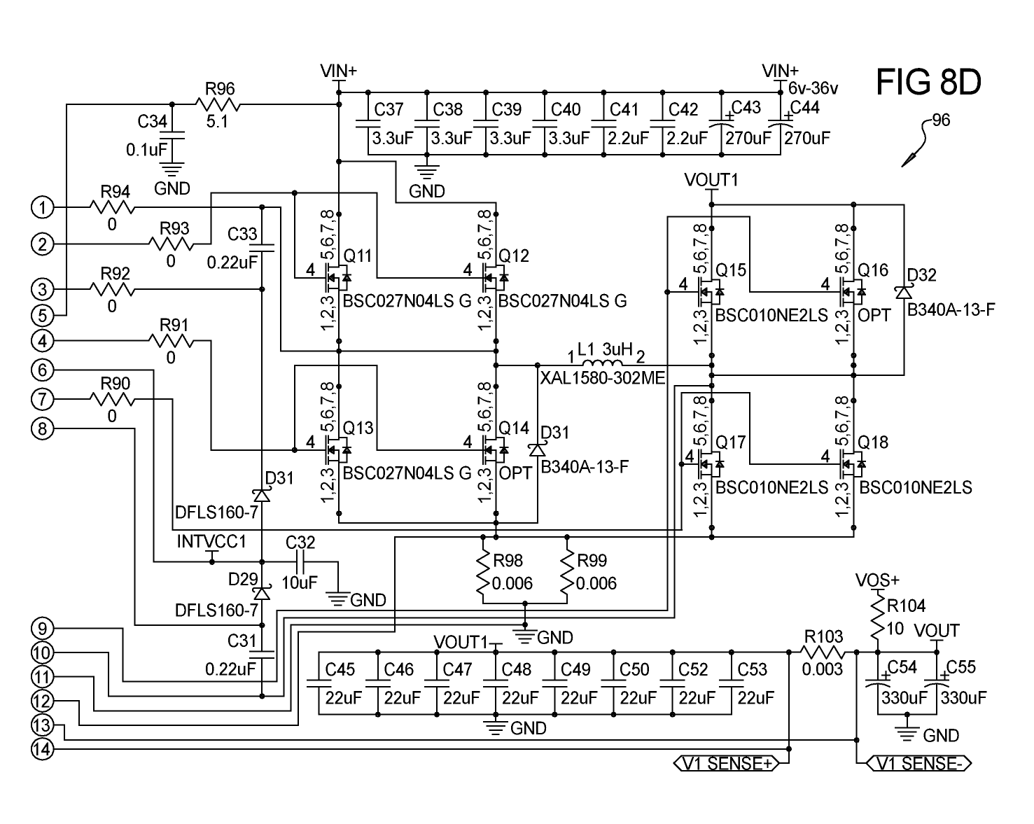

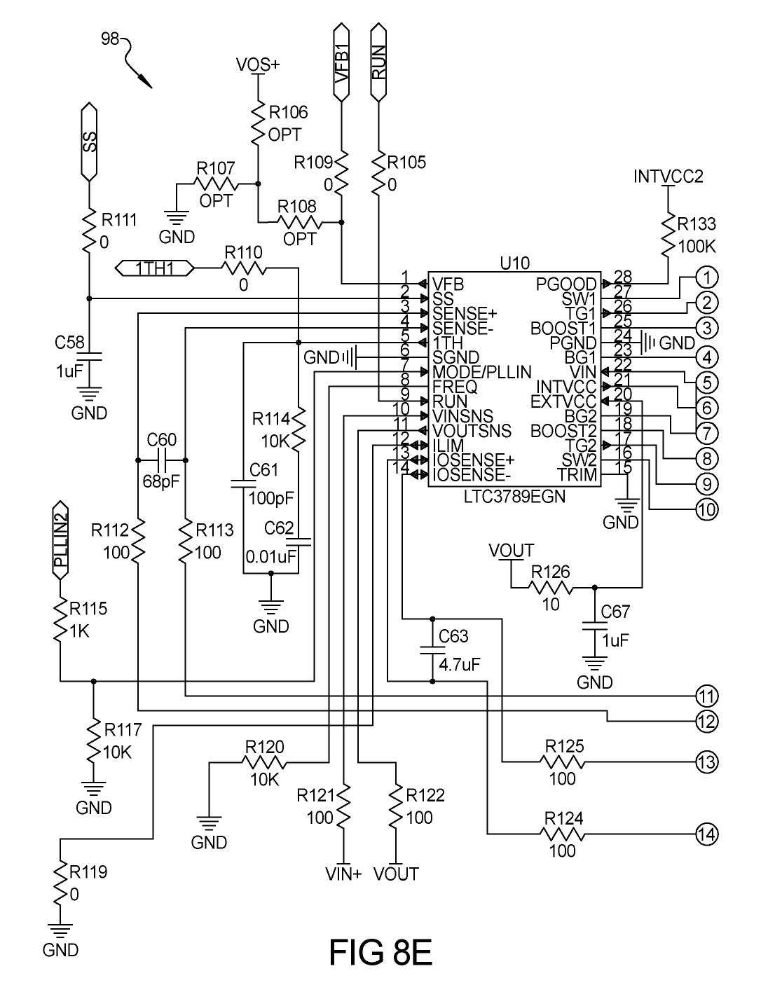

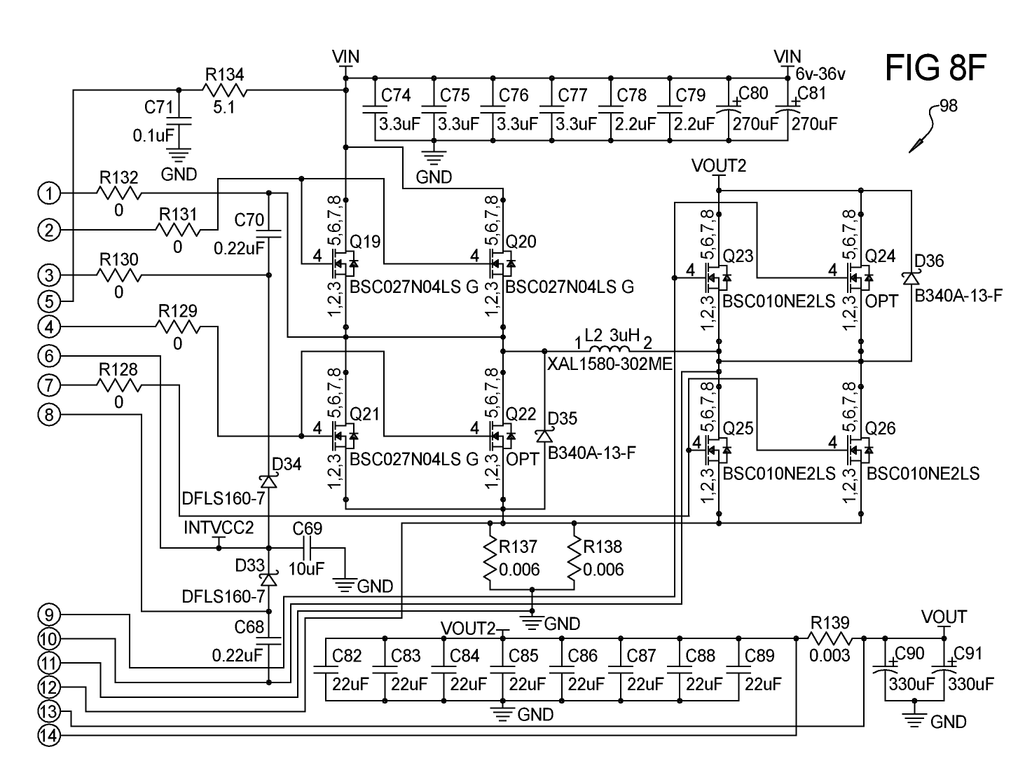

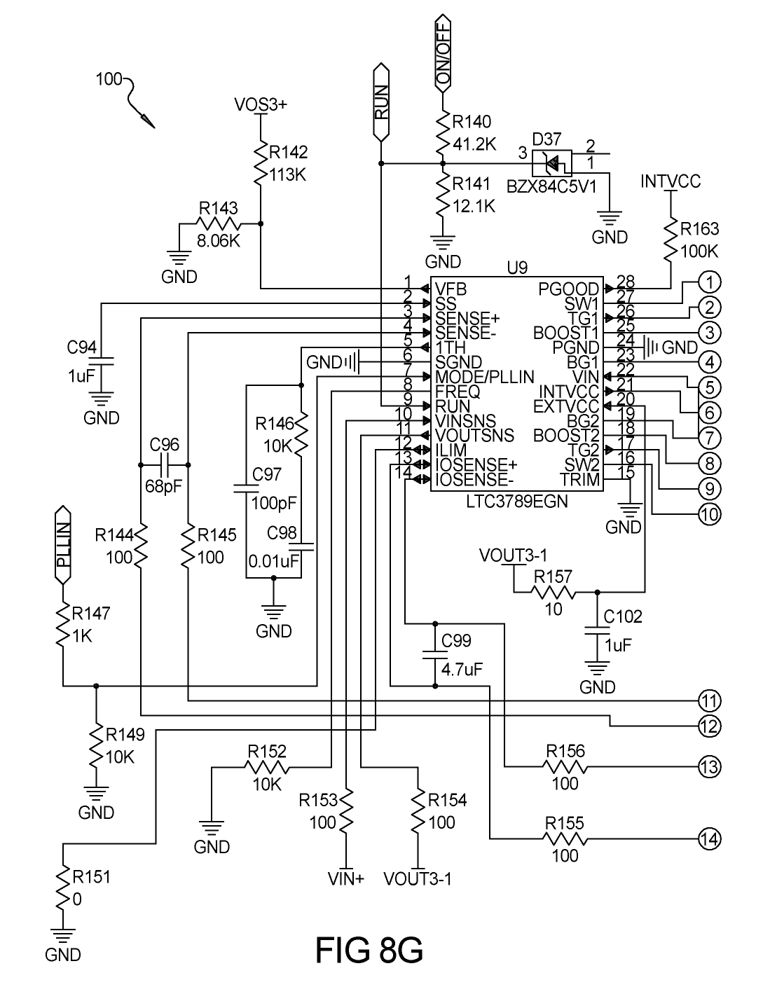

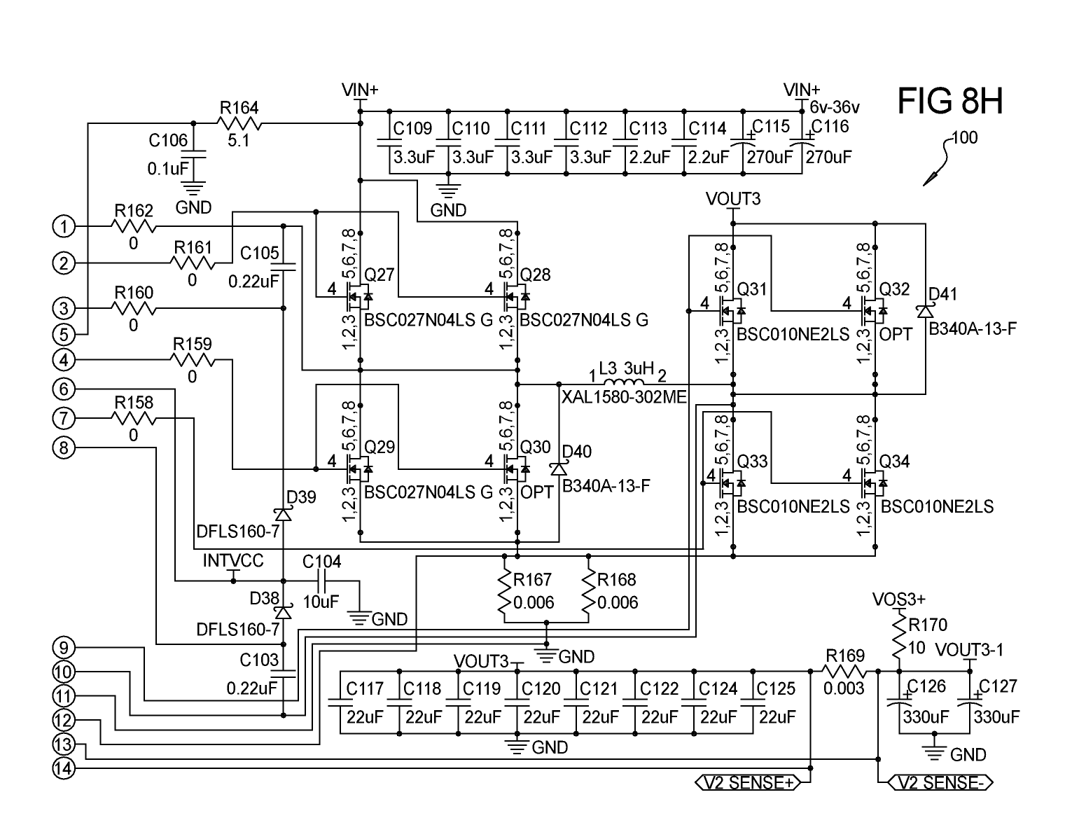

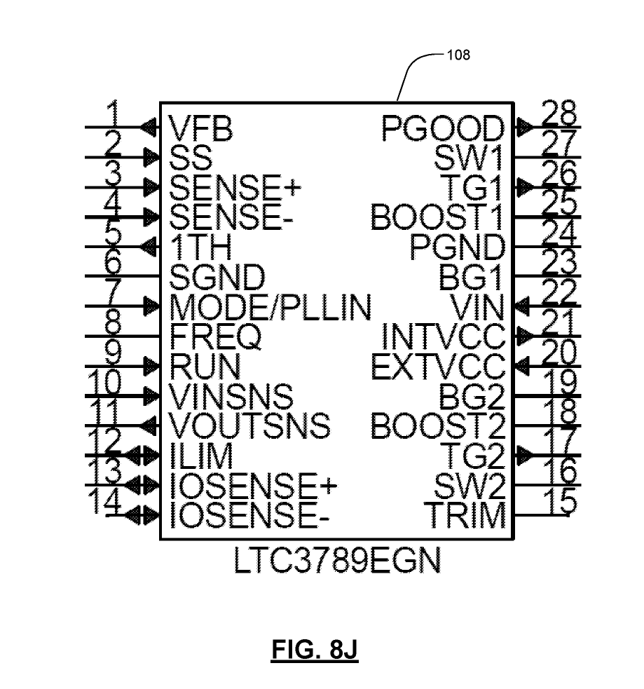

As shown, the battery pack 34 is coupled to the voltage regulator 72. The voltage regulator 72 transforms and regulates the output power from the removable battery pack 34 into the output power needed to energize the output 84. In one example, the output 84 is the one or more electrical control systems of the vehicle. The voltage regulator 72 can be any suitable power regulator. In one example, as further shown in FIGS. 8A-F, a 12 volt buck-boost switching voltage regulator controller or buck-boost converter circuit is used. The 12 volt buck-boost voltage regulator, in the example shown, is connected to the controller 62 using the regulator activation circuit 92. The voltage regulator 72 can include one or more synchronous converter circuits. In the example shown, the voltage regulator 72 includes the first regulator circuit 96 (FIG. 8C), the second regulator circuit 98 (FIG. 8D) and the third regulator circuit 100 (FIG. 8E). The first regulator circuit 96, the second regulator circuit 98 and the third regulator circuit 100 can be coupled in parallel to one another using the oscillator circuit 94 (FIG. 8B). The voltage regulator 72 is configured in this manner to deliver output power with a current in the range of 5-30 Amps.

In the example shown, the first regulator circuit 96, the second regulator circuit 98 and/or the third regulator circuit 100 can be coupled to the oscillator circuit 94 for phase-locked operation. In such a configuration, the first regulator circuit 96 and the second regulator circuit 98 can deliver power signals with differing phase angles (e.g. 180 degrees out of phase from each other) for phase-locked operation. The third regulator circuit 100 can also be similarly coupled to the oscillator circuit 94 for phase-locked operation as well. In other examples, the first regulator circuit 96, the second regulator circuit 98 and/or the third regulator circuit 100 can use an internal clock to operate in a phase-locked manner.

The voltage regulator 72, in the example shown, uses a high efficiency, synchronous 4-switch buck boost controller such as model number LTC3789 manufactured by Linear Technology of Milpitas, Calif. (as shown in FIG. 8F). In other examples, other suitable regulator controllers can be used.

The reverse polarity protector 70 and the switch 40 are connected between the voltage regulator 72 and the battery pack 34. The switch 40 electrically connects and disconnects the battery pack 34 from the voltage regulator 72. As previously discussed, any suitable toggle, push button or rotary switch can be used. The reverse polarity protector 70 protects the components of the power source 30 from a circumstance in which the battery pack 34 (or other energy source) is coupled to the power source 30 with the polarity reversed. A diode or other reverse polarity protection circuit can be used for this purpose.

One example reverse polarity protector circuit is shown in FIG. 7. As shown, this example reverse polarity protector 70 includes a 200 volt, 8 Amp surface mount diode array.

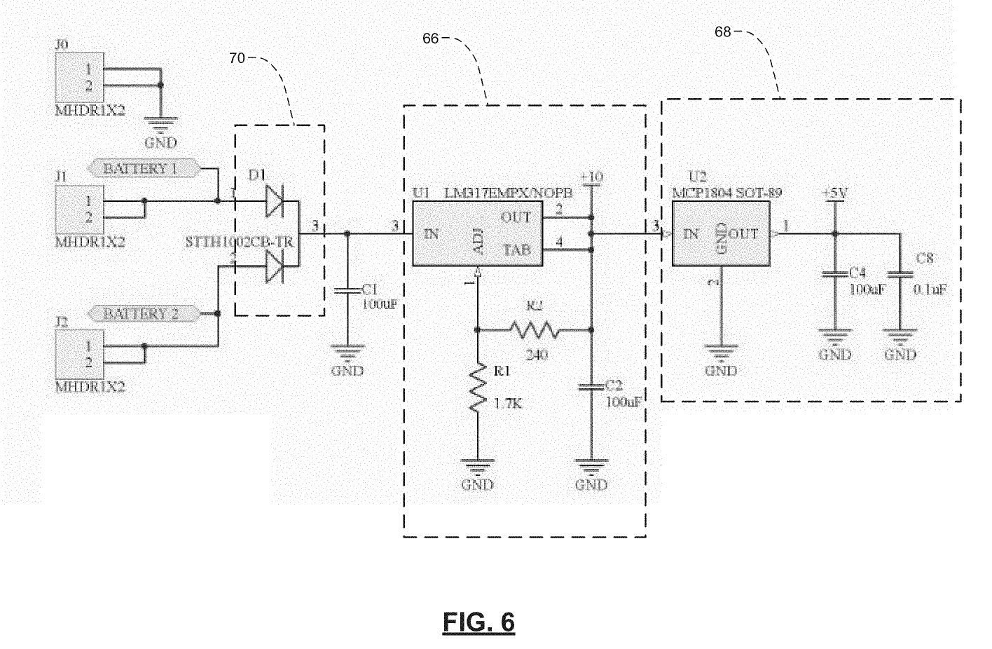

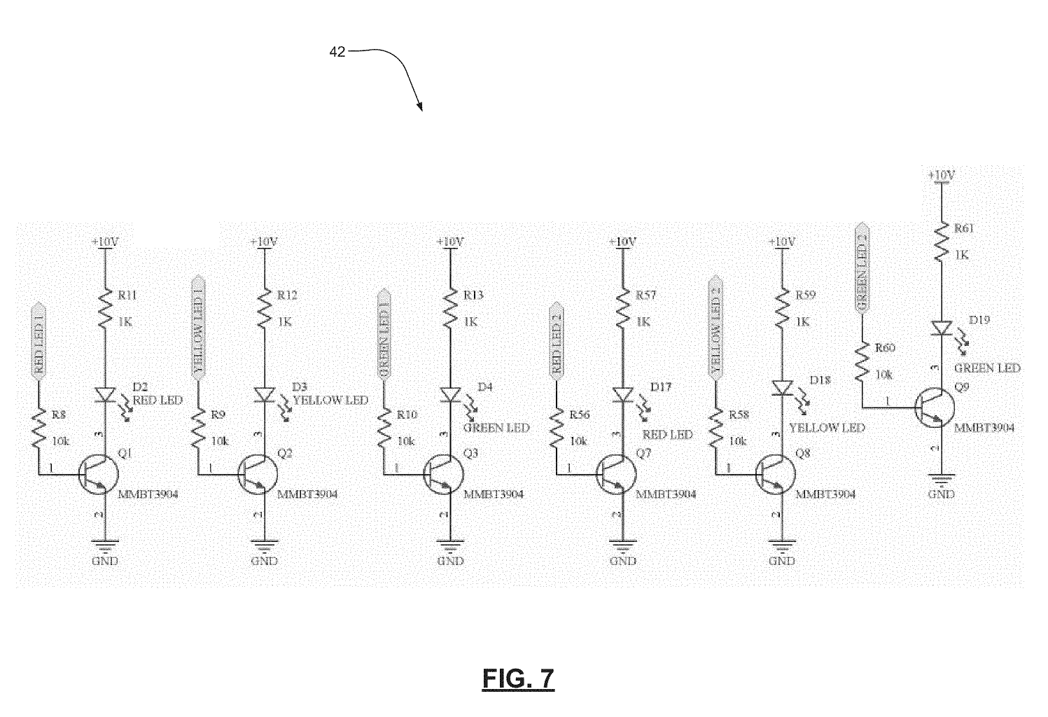

Referring back to FIG. 2, a first regulator 66 and a second regulator 68 are connected between the reverse polarity protector 70 and a controller 62. The first regulator 66 and the second regulator 68 are also electrically coupled to the battery pack 34 and can supply a regulated power source to the controller 62 and/or to the cooling fan 78. In one example (as shown in FIG. 6), the first regulator 66 is a suitable 10 volt regulator such as a wide temperature three-pin adjustable regulator (e.g., model no. LM317EMPX manufactured by Texas Instruments of Dallas, Tex.) and the second regulator 68 is a suitable 5 volt regulator such as a low dropout regulator (e.g., model no. MCP1804 manufactured by Microchip Technology Inc. of Chandler, Ariz.). In other examples, other types or other regulators with different regulated outputs can also be used. In addition, the first regulator 66 and the second regulator 68 can be combined into a single regulator or more than two regulators can be used.

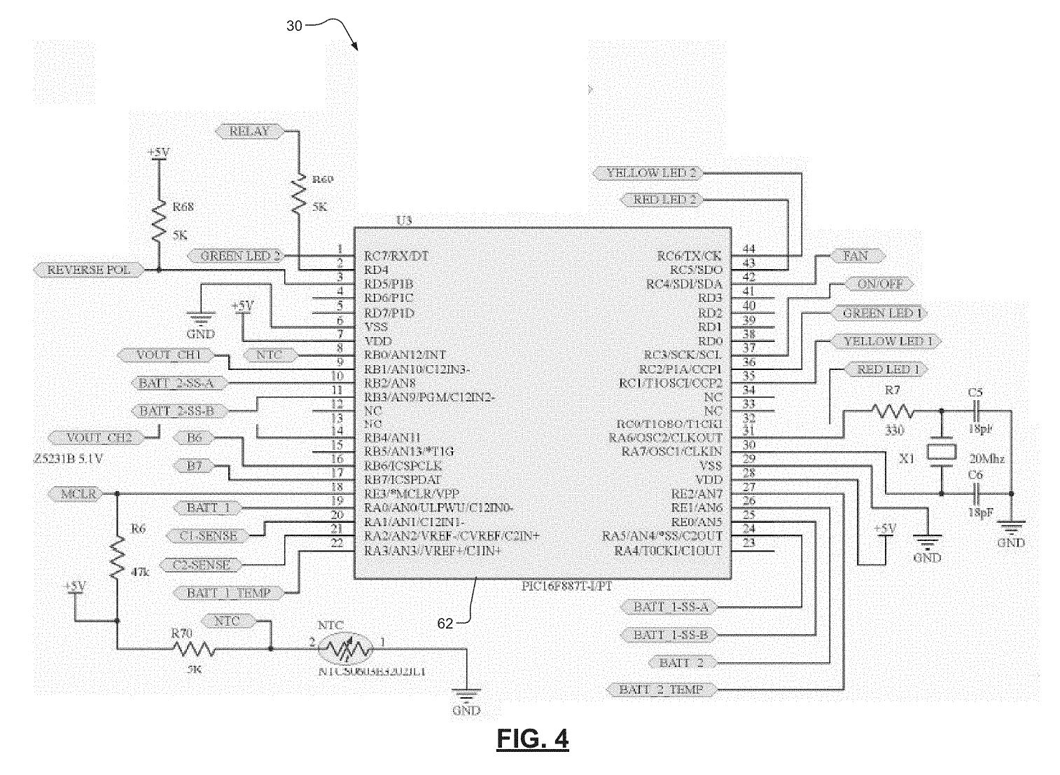

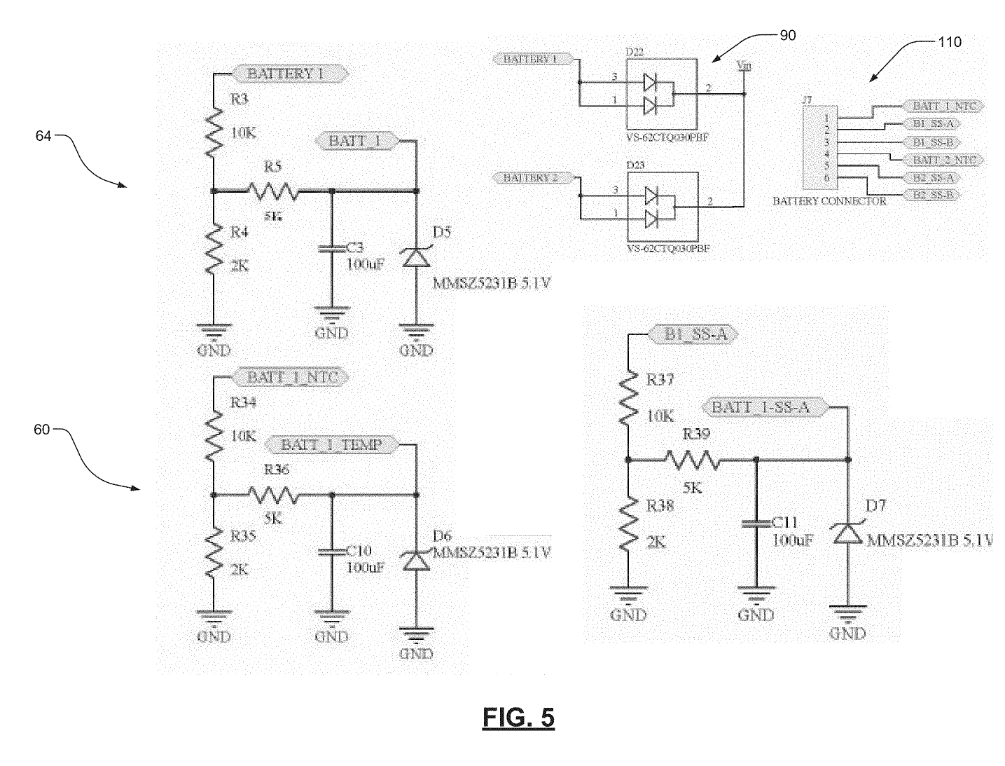

The controller 62 receives power from the first regulator 66 and/or the second regulator 68 and can interact with the other components of the power source 30 to deliver the functionality as will be described. In one example shown in FIGS. 2 and 3, the controller 62 is a suitable micro-controller. The micro-controller can include one or more processors 88 coupled to non-transitory memory 86. The non-transitory memory 86 can have instructions stored thereon to carry out the functionality described below. In other examples, the controller 62 can be a combination of circuits, hardware and/or software such as an application specific integrated circuit or a system on a chip. One example of the controller 62 is shown in FIG. 4. In the example shown, the controller 62 is a Flash-based, 8-bit, CMOS microcontroller such as model number PIC16F887T-I/PT manufactured by Microchip Technology Inc. of Chandler, Ariz.

Referring back to FIG. 2, the controller 62, as shown in this example, is coupled to the voltage regulator 72, a battery pack temperature monitor 60, a battery pack voltage monitor 64, a cooling fan 78, a current sensor 74, a short circuit and over current protector 76, an output voltage monitor 82 and the status indicator 42. The controller 62 can send and receive control signals (as indicated in the dashed lines) from these elements in order to carry out the methods and functionality as described below.

The battery pack temperature monitor 60 and the battery pack voltage monitor 64 are coupled to the controller 62 and to the battery pack 34. The battery pack temperature monitor 60 can be any suitable temperature sensor such as a thermocouple, thermistor or the like. As shown in FIG. 2, the battery pack temperature monitor 60 (or elements thereof) can be included in the housing 32. As shown in FIG. 5 and as previously described, a battery temperature sensor (e.g., a thermistor) can be located inside the battery pack 34 and connected via the circuit shown in FIG. 5 to the controller 62.

The battery pack temperature monitor 60 can send a signal to the controller 62 and the controller 62, in turn, can determine a temperature of the battery pack 34 during operation of the power source 30. The controller 62 can then take further actions (e.g., interrupt the connection of the battery pack 34 to the output 84 by moving a switch in the voltage regulator 72 from an on state to an off state) if the signal from the battery pack temperature monitor 60 indicates that the battery pack 34 is above a predetermined temperature threshold. The controller 62 can interrupt the connection of the battery pack 34 from the output 84 to prevent the battery pack 34 from being damaged.

The battery pack voltage monitor 64 can be any suitable voltage sensor and/or related circuitry. The battery pack voltage monitor 64 (or elements thereof) can be located in the housing 32 or located in the battery pack 34. In one example, the battery pack voltage sensor is located inside the battery pack 34. The battery pack voltage sensor is then connected to the controller 62 using the circuit shown in FIG. 5.

In the example battery pack 34 that includes six battery terminals, the battery pack 34 can be connected to the controller using the battery connector 110 shown in FIG. 5. The battery connector 110 can connect the internal circuits such as a battery temperature sensor and a battery voltage sensor that are located inside the battery pack 34 to the controller 62.

The battery pack voltage monitor 64 can send a signal to the controller 62 that indicates a battery voltage level of the battery pack 34. The controller 62 can receive such signals from the battery pack voltage monitor 64 during operation of the power source 30. As will be further described below, the controller 62 can determine, after receiving the signal(s) from the battery pack voltage monitor 64, whether subsequent actions need to be taken or if the voltage level of the battery pack 34 is at or above one or more predetermined voltage thresholds such that the connection of the battery pack 34 to the output 84 should be disconnected and/or whether the power source 30 should indicate a change in condition of the voltage level of the battery pack 34 via the status indicator 42 to the user.

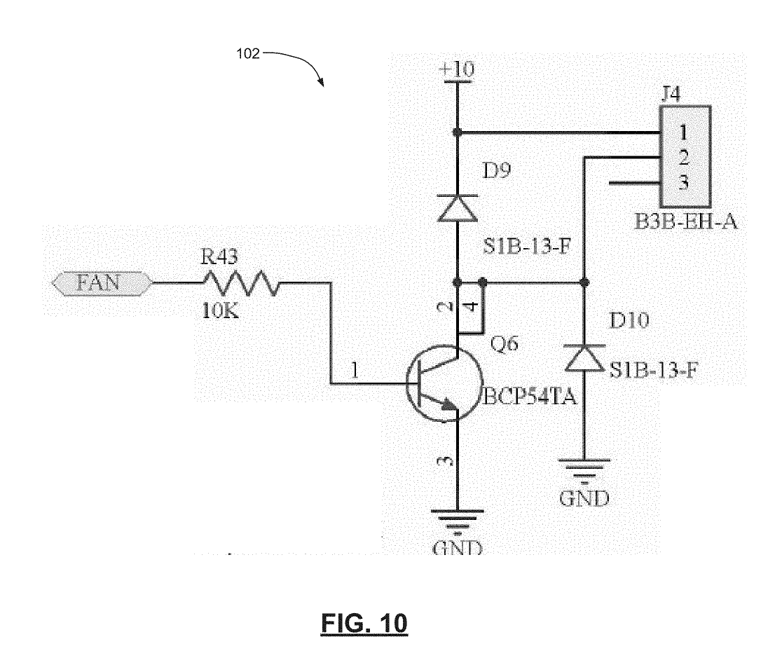

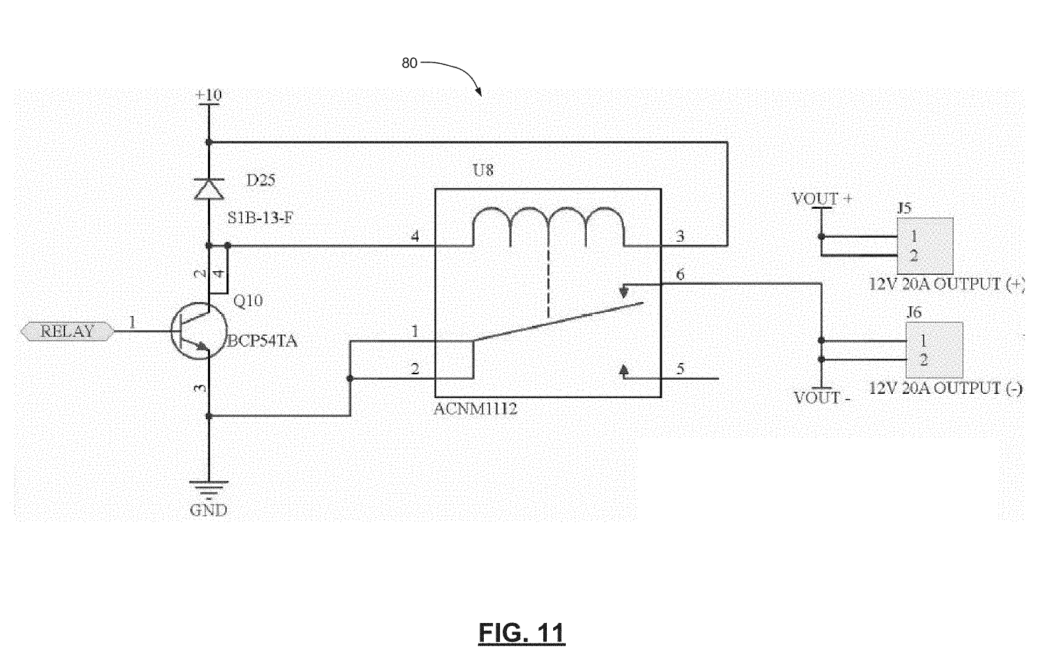

As shown in FIG. 2, the controller 62 is also coupled to the cooling fan 78. The controller 62 can send a control signal to the cooling fan 78 in order to energize or de-energize the cooling fan 78. In one example, the controller 62 can be connected to the cooling fan using the fan connection circuit 102 shown in FIG. 10. In one example, the controller 62 instructs the cooling fan 78 to turn on when the power source 30 is in operation. In other examples, the controller 62 can determine when one or more of the components is at an elevated temperature and then signal the cooling fan 78 to turn on when the elevated temperature is reached. Similarly, the controller 62 can signal the cooling fan 78 to turn off when a component is no longer at or above the elevated temperature.

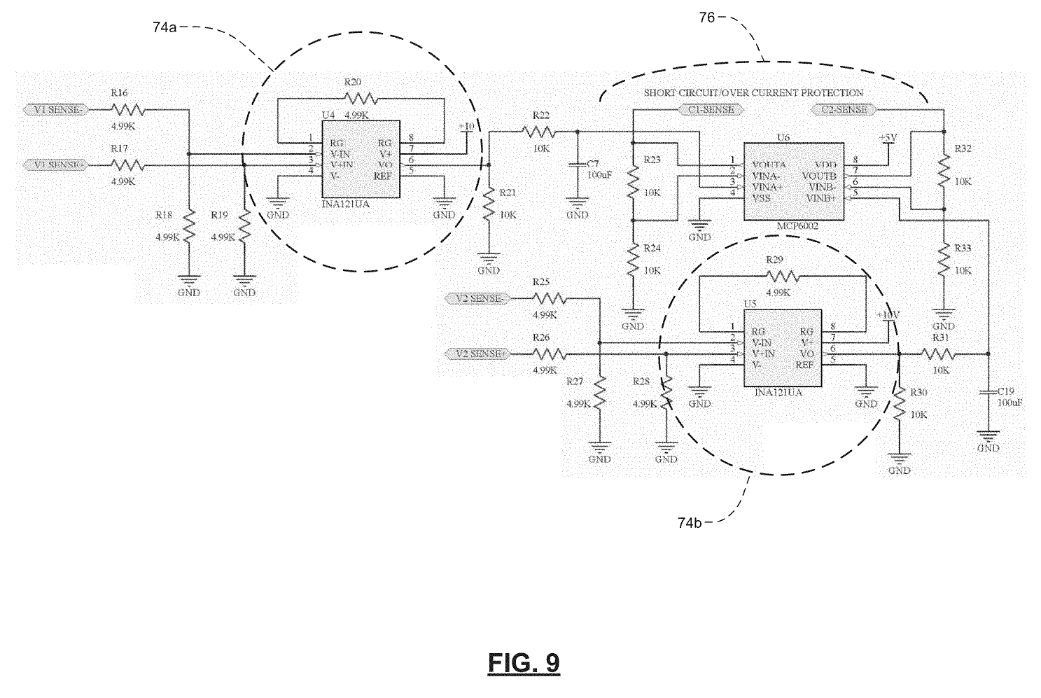

The short circuit and over current protector 76, in the example shown, is connected between the current sensor 74 and the controller 62. The short circuit and over current protector 76 prevents damaging current levels at the output 84. Any suitable short circuit and/or over current protector can be used. An example short circuit and over current protector 76 is shown in FIG. 9 and its operation is further described below.

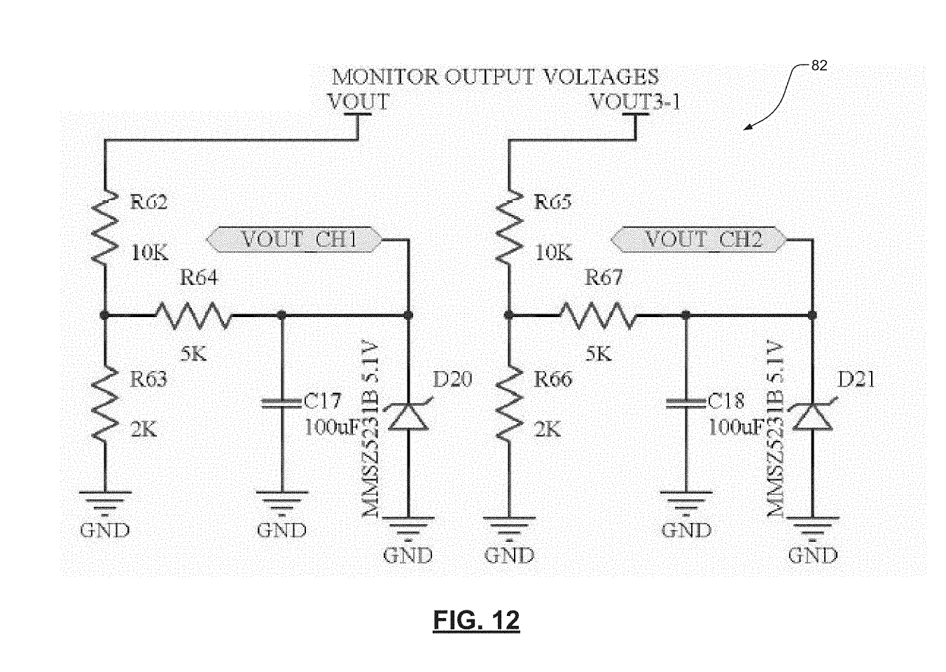

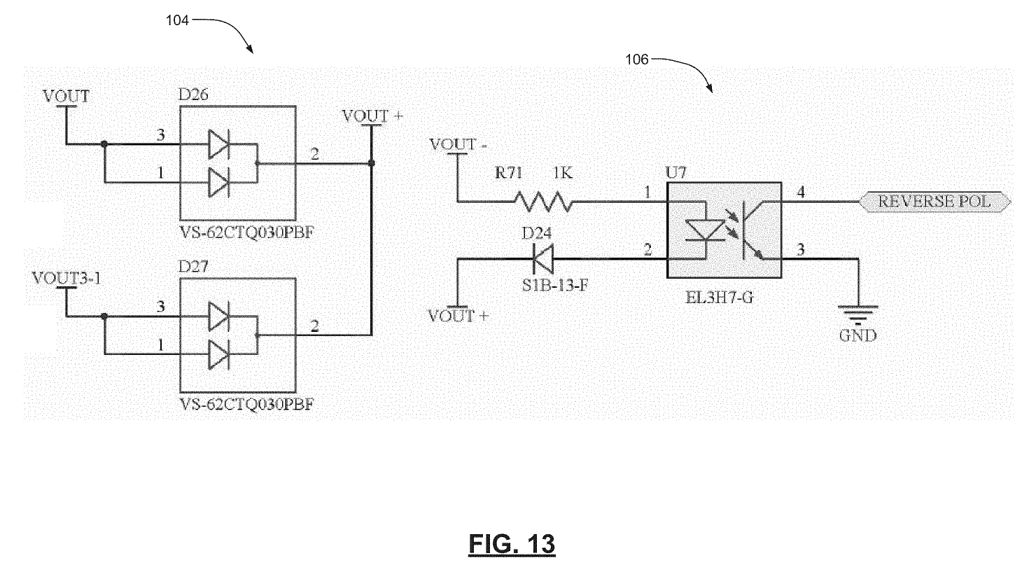

Referring back to FIG. 2, the output voltage monitor 82 is connected between the output 84 and the controller 62. The output voltage monitor 82 can send a signal to the controller 62 that the controller 62 can be used to determine the voltage of the output power being delivered by the power source 30. The output voltage monitor 82 differs from the battery pack voltage monitor 64 in that the output voltage monitor 82 assists the controller 62 in monitoring the voltage level of the output power being delivered by the power source 30 while the battery pack voltage monitor 64 assists the controller 62 in monitoring the voltage level of the battery pack 34. Since the energy of the battery pack 34 is being transformed and/or regulated by the voltage regulator 72 before being delivered to the output 84, the voltage level of the battery pack 34 is different from the voltage level of the output power being delivered to the output 84. The output voltage monitor 82 can include any suitable voltage sensor. In one example, the output voltage monitor 82 can include the circuit shown in FIG. 12.

In addition to monitoring the voltage level of the output power, the controller 62 can determine a current level of the output power being delivered to the output 84. The current sensor 74 is coupled to the controller 62 and is positioned in series between the voltage regulator 72 and the output 84. One example includes a first current sensor 74a and a second current sensor 74b coupled to the current sensor as shown in FIG. 9. The current sensors 74a,b can send a signal (or signals) to the controller 62 that the controller 62 can use to determine the current level of the output power being delivered to the output 84.

The controller 62 can compare the current level to one or more predetermined current thresholds and take action as desired. In one example, the controller 62 can compare the current level to a predetermined current threshold and if the current level is greater than the predetermined current threshold, the controller 62 can interrupt the circuit between the battery pack 34 and the output 84. It may be desirable to take such action to prevent damage from occurring to the battery pack 34 or to other components of the power source 30.

While not shown in FIG. 2, the power source 30 can include other components to provide further flexibility and/or further functionality. As previously described, the power source 30, in another example, can include one or more wireless transceivers that can couple the power source to a wireless communication protocol. Such examples can permit the power source 30 to be coupled (wirelessly or otherwise) to the internet, to one or more remote servers or to other mobile computing devices. Such a transceiver can permit the power source 30 to transmit or receive data regarding the operation of the power source 30 and/or the output 84.

In still another example, the power source 30 can include one or more input connectors such as a USB, Mini-USB or Micro-USB port. Such an input connector can permit a user to couple an external storage device and/or an external computing device to the power source 30. In this manner, the controller 62 can be reconfigured, reprogrammed or a user can download data regarding the operation of the power source 30. In still other examples, other communication, connectors and interfaces can be included in power source 30 to further permit the power source 30 to interact with external computing device or to be reconfigured, reprogrammed, updated or maintained as desired.

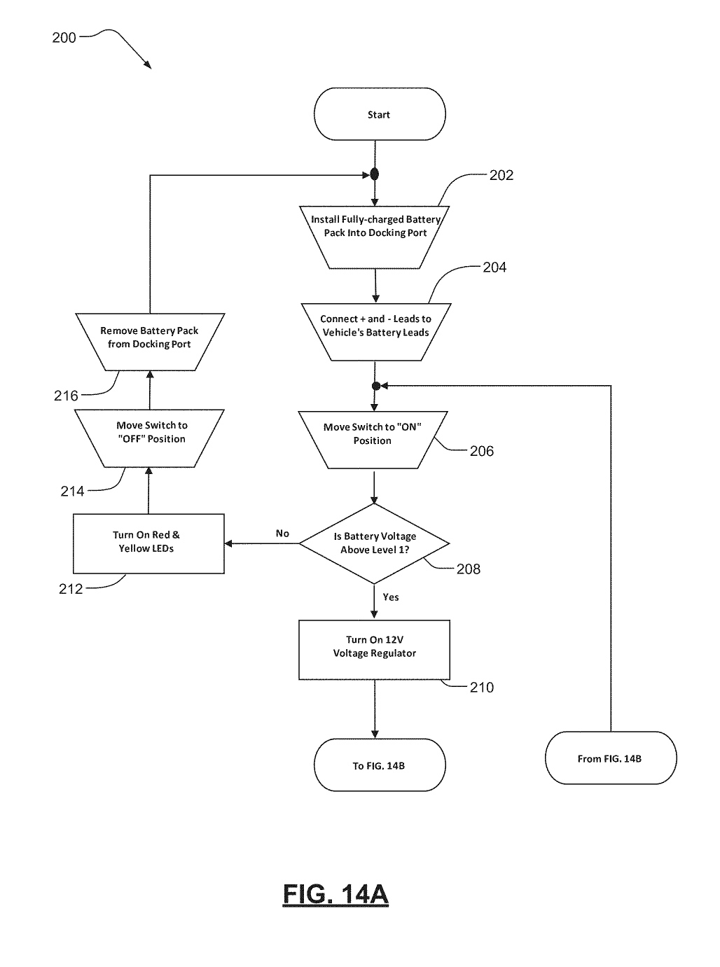

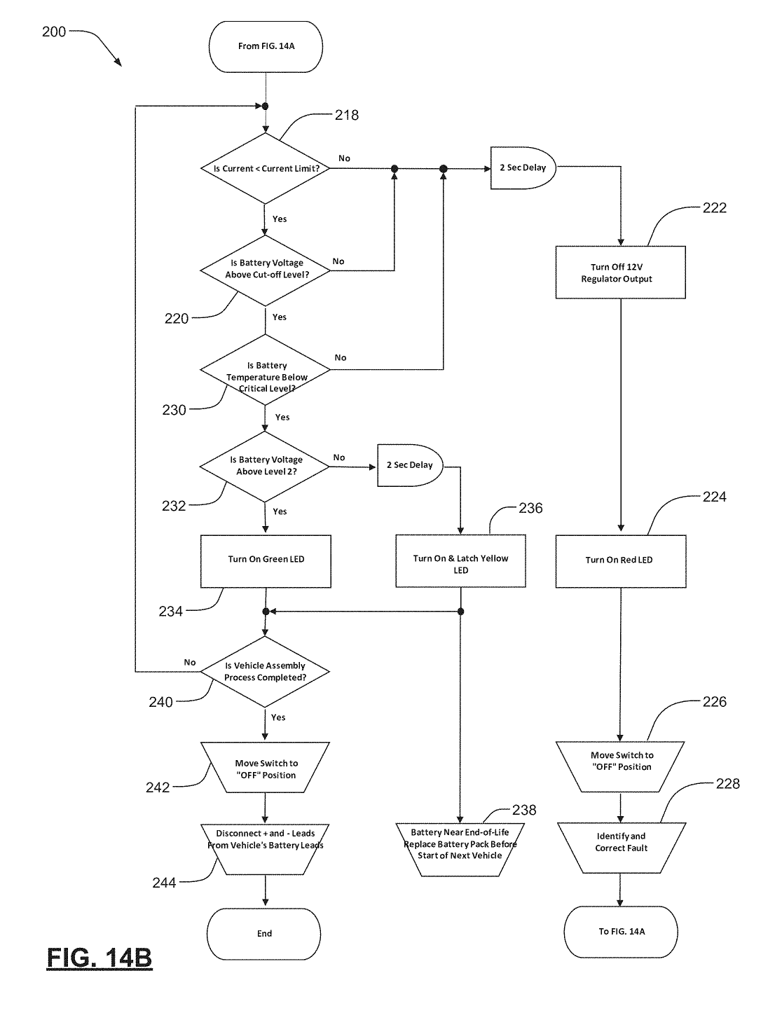

Referring now to FIGS. 14A and 14B, one example method of using the power source 30 is shown. In the example, a method 200 of powering a vehicle during an assembly process of the vehicle is shown. By using the example method 200, a user can power the vehicle in order that one or more electrical control systems of the vehicle can be programmed.

As shown, the example method 200 begins at step 202. At 202, a fully-charged battery pack 34 is installed into the docking port 38 of the power source 30. While not shown, the battery pack 34 can be charged using a suitable charger. In an embodiment in which the battery pack 34 is a rechargeable power tool battery pack, a stand-alone battery charger can be used to charge the battery pack. In this manner, a user can be charging one or more battery packs 34 so that a fully-charged battery pack 34 is always available for use. As can be appreciated, this can be particularly advantageous in the context of vehicle assembly so that the power source 30 can continuously be used on the assembly line without interruption by swapping depleted battery packs 34 with fully-charged battery packs 34.

At step 204, the pair of cable 36 is connected to the battery leads 48 of the vehicle that needs to be powered for programming. In the context of a vehicle assembly process, the housing 32 of the power source 30 can be placed into the battery tray 44 of the vehicle. Since the vehicle's automotive battery has not been installed at this stage of vehicle assembly, the battery tray 44 is empty. The housing 32 can be placed in the battery tray 44 and the pair of cables 36 can be connected to the battery leads 48 of the vehicle using, for example, the positive connector 50 and the negative connector 52. In other examples and in other contexts, the power source 30 can be positioned elsewhere in the vehicle and can be coupled to the vehicle's electrical control systems using alternate connectors.

At step 206, a user moves the switch 40 to the “ON” position. In this manner the user initiates the power source 30. In other examples, the user can initiate the power source 30 using a different input device and/or can initiate the power source 30 remotely if the power source 30 is connected (wirelessly or otherwise) to other computing devices.

Once the power source 30 is initiated, the battery pack 34 provides power to the controller 62 and to the various sensors, monitors and other components of the power source 30 using the first regulator 66 and/or the second regulator 68. At step 208, the controller 62 determines if the battery voltage is greater than a first predetermined voltage threshold (e.g., Level 1, as shown in FIG. 14A). The controller 62, in the example power source 30 shown in FIG. 2, receives a signal from the battery pack voltage monitor 64. Using this signal, the controller 62 is able to determine the battery voltage of the battery pack 34 and can then compare this battery voltage to the first predetermined voltage threshold.

The first predetermined voltage threshold is a voltage threshold of the battery pack 34 that ensures that the power source 30 can deliver output power to the vehicle's electrical control systems for a sufficient period of time to fully program the electrical control system(s). As stated above, it is undesirable to interrupt the output power to the vehicle's electrical control system(s) during programming. In one example vehicle, the programming of the vehicle's electrical control systems lasts for approximately 30 minutes. If the power source 30 is used to power this vehicle's electrical control systems during programming, the first predetermined threshold ensures that the power source 30 can deliver the output power for at least 30 minutes. In an example power source 30 using a 20 volt, 9 Amp-hour power tool battery or tool battery pack, the first predetermined voltage threshold can be 19 volts. In other examples, the first predetermined voltage threshold can be other values.

If the controller 62 determines that the battery voltage is greater than the first predetermined threshold, the method 200 continues to step 210. If the controller 62 determines that the battery voltage is not greater than the first predetermined threshold, the controller 62 turns on the red LED light and the yellow LED light on the status indicator 42. The red LED light is an indication of a fault condition of the power source 30. The yellow LED light is an indication of a low-level charge condition of the battery pack 34. The controller 62 indicates the fault condition and the low-level charge condition because the power source 30 should not be used with the current battery pack 34 if the battery voltage is not greater than the first predetermined voltage threshold. This would indicate that the battery pack 34 does not have a sufficient capacity to provide output power to the vehicle's electrical control systems for a complete programming cycle.

After indicating the fault condition and the low-level charge condition (i.e., the red LED light and the yellow LED light), a user moves the switch 40 to the “OFF” position. Since the red LED light and the yellow LED light are illuminated on the status indicator 42, a user would know that the battery pack 34 does not have a sufficient capacity. At step 216, the battery pack 34 is removed from the docking port 38 and can be re-charged or an alternate battery pack 34 can be used to re-start the method 200 at step 202.

Referring back to step 208, the method 200 continues if the controller 62 determines that the battery voltage is greater than the first predetermined voltage threshold. At step 210, the controller 62 activates (i.e., turns on) the voltage regulator 72. The voltage regulator 72 receives the input signal from the battery pack 34 and transforms the battery pack signal to the output power that is suitable to power the electrical control systems of the vehicle. At this step, the vehicle's electrical control system(s) begin to draw power from the battery pack 34.

At step 218, the controller 62 determines if the output current of the output power flowing to the vehicle's electrical control system(s) is greater than a predetermined current threshold. In the example power source 30 of FIG. 2, the current sensor 74 sends a signal to the controller 62. The controller 62 uses this signal to determine the output current of the output power flowing to the vehicle's electrical control systems. If the controller 62 determines that the output current is not greater than the predetermined current threshold, the method 200 continues at step 220.

If the controller 62 determines that the output current is greater than the predetermined current threshold, the controller 62 deactivates (turns off) the voltage regulator 72 at step 222. At step 224, the controller 62 further turns on the red LED light (or otherwise indicates the fault condition). As this stage of the method 200, the user would know that a fault has occurred given the fault condition indicated on the status indicator 42 and would move the switch to the “OFF” position (step 226) and identify and correct the fault (step 228) before attempting to restart the power source 30 at step 206 as shown.

The foregoing determination of the output current by the controller 62 can identify when a short circuit may be present. For example, there may be short circuit in the vehicle's electrical control system(s), between the pair of cables 36 and/or between the battery leads 48. The controller 62 can determine if such a short circuit condition exists and turn off the power source 30 before it or the vehicle's electrical controls system(s) is damaged. In one example the predetermined current threshold is 30 Amps. In other examples, the predetermined current threshold can be more than or less than 30 Amps.

When the vehicle's electrical control system(s) begins to draw power from the battery pack 34, there can be an initial in-rush of current that can cause a spike in the output current of the power source 30. For this reason, the example method can include a time delay between the time that the controller 62 determines if the output current is greater than the predetermined current threshold and when the controller 62 deactivates the voltage regulator 72 at step 222. In the example shown, the method 200 includes a two second delay. In other examples, the time delay can be more than or less than a two second delay. The controller 62 includes a timer that can cause the time delay between actions in the method 200.

At step 220, the controller 62 determines if the battery voltage is greater than a second predetermined voltage threshold. The controller 62 can determine if the battery voltage is greater than the second predetermined threshold in a manner similar to that previously described at step 208. For example, the battery pack voltage monitor 64 can send a signal to the controller 62 that the controller 62 uses to determine the battery voltage and then compares the battery voltage to the second predetermined voltage threshold.

If the controller 62 determines that the battery voltage is greater than the second predetermined voltage threshold, the method 200 continues at step 230. If the controller 62 determines that the battery voltage is not greater than the second predetermined threshold, the method 200 proceeds to step 222. The method continues at step 222 and a fault is corrected before the method 200 is restarted at step 206.

The controller 62 determines if the battery voltage is greater than the second predetermined voltage threshold to ensure that the battery voltage does not fall below a cut-off level. If the battery charge falls below the cut-off level, the battery pack 34 can be permanently damaged. In an example battery pack 34 that uses a 20 volt, 9 Amp-hour power tool battery pack, the second predetermined voltage threshold (i.e., the cut-off level of the battery pack) can be 15 volts. In other examples, the second predetermined voltage threshold can be more than or less than 15 volts.

At step 230, the controller 62 determines if a battery temperature of the battery pack 34 is greater than a predetermined temperature threshold. The controller 62 can, for example, receive a signal from the battery pack temperature monitor 60. The controller 62 uses this signal to determine the temperature of the battery pack 34. The controller 62 then compares the temperature of the battery pack 34 to the predetermined temperature threshold. If the controller 62 determines that the temperature of the battery pack 34 is not greater than the predetermined temperature threshold, the method 200 continues at step 232.

If the controller 62 determines that the temperature of the battery pack 34 is greater than the predetermined temperature threshold, the controller 62 takes the same steps as previously described at step 222 (and the subsequent steps 224 and 226). Since a fault condition is indicated on the status indicator 42 by the controller 62 at step 224, the user would identify and correct the fault at step 228 before attempting to restart the method 200 at step 206.

The controller 62 determines if the temperature of the battery pack 34 is greater than the predetermined temperature threshold in order to prevent damage from occurring to the battery pack 34. For example, if the battery pack 34 experiences a significant amount of current draw for an extended period of time, the battery pack 34 can begin to heat up. If the battery pack 34 heats to temperatures above the predetermined temperature threshold, the battery pack 34 can be permanently damaged. In addition, the battery pack 34 could damage the docking port 38 and/or other components of the power source 30.

While not shown in FIGS. 14A and 14B, the controller 62 can energize the cooling fan 78 in response to determining that the temperature of the battery pack 34 is greater than a predetermined cooling threshold. The controller 62 can determine, in response to the signal received from the battery pack temperature monitor 60, that the battery pack is at an elevated temperature but has not yet reached the predetermined temperature threshold. In such an instance, the controller can energize the cooling fan 78 that can move air through the housing to cool the components of the power source 30 and/or the battery pack 34.

At step 232, the controller 62 determines if the battery voltage is greater than a third predetermined voltage threshold. The controller 62 can determine the battery voltage by interacting with the battery voltage monitor 64 as previously described. If the controller determines that the battery voltage is greater than the third predetermined voltage threshold, the method 200 continues at step 234.

If the controller 62 determines that the battery voltage is not greater than the third predetermined voltage threshold, the method 200 proceeds to step 236. At step 236, the controller 62 turns on the yellow LED light (i.e., the low-level charge condition indicator) on the status indicator 42. The controller 62 can additionally latch the yellow LED light. The controller 62 can latch the yellow LED light in an illuminated condition so that the light will stay illuminated until the user takes appropriate action to address the low-level charge condition.

The third predetermined voltage threshold corresponds to the low-level charge condition of the battery pack 34. When the battery pack 34 does not have a voltage level above the third predetermined threshold, the battery pack 34 is nearing its end of life and does not have sufficient capacity to provide suitable output power for the programming of another vehicle's electrical control system(s). While the battery pack 34 may have sufficient capacity to complete the programming of the vehicle's electrical control system that is underway, the battery pack 34 should not be used for the programming of another vehicle without recharging. For this reason, the controller 62 indicates the low-level charge condition on the status indicator 42 by illuminating the yellow LED light in this example. This indicates to the user that the user should remove the battery pack 34 from the docking port and recharge the battery pack 34 when the reprogramming process that is currently underway is complete. In an example battery pack 34 that is a 20 volt, 9 Amp-hour power tool battery pack, the third predetermined voltage threshold can be 18 volts. In other examples, the third predetermined voltage threshold can be values greater than or less than 18 volts.

At step 234, the controller 62 turns on the green LED light on the status indicator 42. The green LED light, in this example, indicates the operating condition of the power source 30. In the operating condition, the output current is not greater than the predetermined current threshold, the battery voltage is greater than the first predetermined threshold, the battery voltage is greater than the second predetermined threshold, the battery temperature is not greater than the predetermined temperature threshold and the battery voltage is greater than the third predetermined voltage threshold. In the operating condition, the power source 30 is able to provide suitable output power to the output 84 (i.e., the one or more vehicle electrical control systems) without the risks of damage to the battery pack 34, the power source 30 and/or the vehicle's electrical control system(s).

At step 240, the controller 62 determines whether the vehicle assembly/programming process is complete. Alternatively, an operator may monitor the programming process to determine if the programming process is complete. If the programming process of the vehicle's electrical control system(s) is not complete, the method 200 returns to step 218 and the output current, the battery voltage of the battery pack 34 and the battery temperature of the battery pack 34 are monitored and compared against the predetermined current, temperature and voltage thresholds as previously described.

If the vehicle assembly/programming process is complete, the method 200 continues to step 242. At step 242, a user moves the switch 40 to the off position. The user can then disconnect the pair of cables 36 from the battery leads 48 at step 244 and the method 200 ends. While not shown, the user can then move the power source 30 to another vehicle and then restart the method 200 to program a second vehicle. If the controller 62 determined that battery voltage was not greater than the third predetermined voltage threshold, the status indicator 42 would be indicating the low-level charge condition at the conclusion of the programming process. If this occurred, the user could replace the battery pack 34 with a fully-charged battery pack before using the power source 30 to restart the method 200 with the second vehicle. The user could also re-charge the battery pack 34 that exhibited the low-level charge condition.

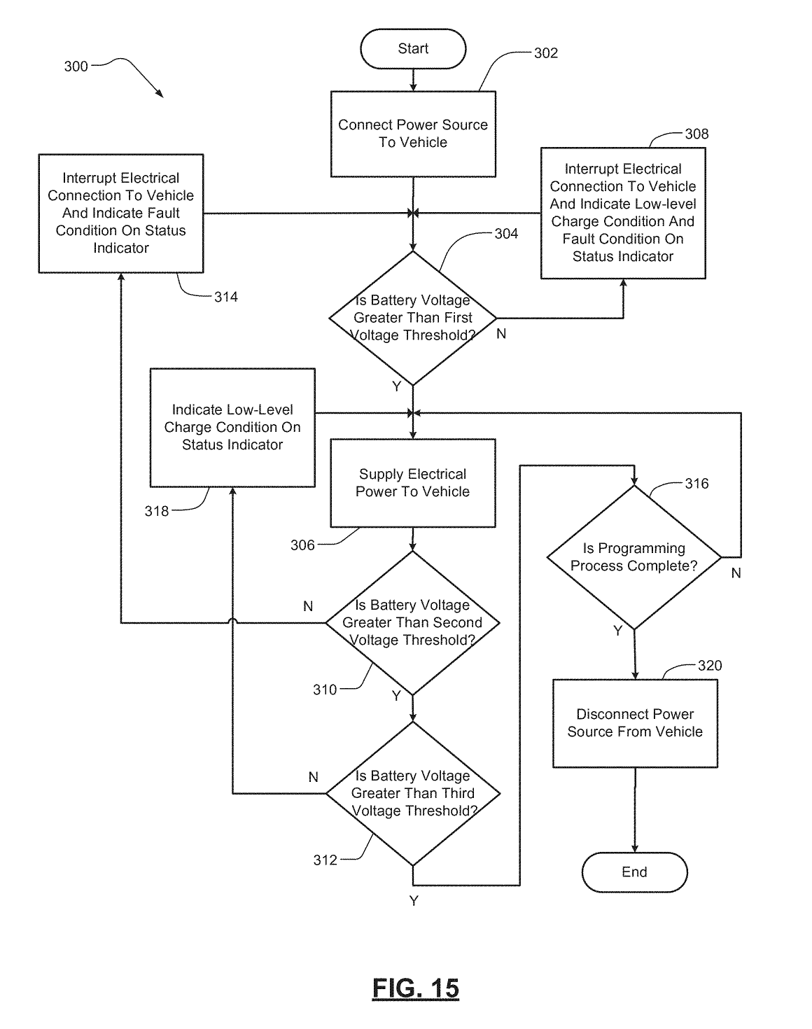

Referring now to FIG. 15, another example method 300 is shown. The example method 300 is similar to the example method 200. The method 300 starts at step 302. At step 302, the power source 30 is connected to the vehicle. The power source 30 can be connected to the vehicle using any suitable connector or method and, in the example power source 30 of FIG. 2, is connected to the vehicle using the pair of cables 36.

At step 304, the controller 62 determines if the battery voltage is greater than the first predetermined voltage threshold. The controller 62 determines the battery voltage as previously described and then compares the battery voltage to the first predetermined voltage threshold. If the battery voltage is greater than the first predetermined voltage threshold, the method 300 continues at step 306. If not, the controller 62 interrupts the connection of the battery pack 34 to the vehicle and indicates the low-level charge condition and fault condition on the status indicator 42. The controller 62 can interrupt the connection of the battery pack 34 to the vehicle by instructing the voltage regulator 72 not to provide output power to the vehicle and/or by opening the circuit between the battery pack 34 and the vehicle. The user then takes appropriate action to correct the fault condition before the method 300 is restarted at step 304.

At step 306, the controller 62 supplies electrical power to the vehicle. The controller 62, in one example, can instruct the voltage regulator 72 to begin providing electrical power to the vehicle and/or close the circuit between the battery pack 34 and the vehicle. After this occurs, the controller 62, at step 310, determines if the battery voltage is greater than the second predetermined voltage threshold. The controller 62 can make this determination as previously described. If the battery voltage of the battery pack 34 is greater than the second predetermined voltage threshold, the method 300 continues to step 312. If not, the controller 62 interrupts the electrical connection to the vehicle and indicates the fault condition on the status indicator 42. The user then takes appropriate action to correct the fault condition before the method 300 is restarted at step 304.

At step 312, the controller 62 determines if the battery voltage is greater than the third predetermined voltage threshold. If the battery voltage is greater than the third predetermined voltage threshold, the method continues at step 316. If not, the controller 62 causes the low-level charge condition to be indicated on the status indicator 42 and the method 300 continues at step 306.

At step 316, the method 300 returns to step 306 if the process of programming the one or more electrical control systems of the vehicle is not complete. The controller 62 in combination with the monitors, sensors and other components of the power source 30 continue to compare the battery voltage to the predetermined voltage thresholds until the programming process is complete. Once the programming process is complete, the power source 30 can be disconnected from the vehicle at step 320 and the method 300 ends.

The foregoing example power source 30 and the related methods of use can be used to program one or more electrical control systems of a vehicle in an assembly environment. The power source 30 can be used to reliably program a vehicle's electrical control systems without the need for complex, cost-intensive equipment that is incorporated into existing conveyors or other vehicle assembly plant equipment. As can be appreciated, the power source 30 can also be used in other environments in which a reliable, portable power source is needed to power vehicles. Still further, the example power sources and related methods can also be used to power other equipment or other machines that may need temporary reliable power for repair, assembly or maintenance.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

In this application, including the definitions below, the term “module” or the term “controller” may be replaced with the term “circuit.” The term “controller” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The controller may include one or more interface circuits. In some examples, the interface circuits may include wired or wireless interfaces that are connected to a local area network (LAN), the Internet, a wide area network (WAN), or combinations thereof. The functionality of any given controller of the present disclosure may be distributed among multiple controllers that are connected via interface circuits. For example, multiple controllers may allow load balancing. In a further example, a server (also known as remote, or cloud) module may accomplish some functionality on behalf of a client controller.

What is claimed is:

1. A portable power source for powering one or more electrical control systems of a vehicle during programming thereof while the vehicle moves through multiple stages of an assembly line, the portable power source comprising:
a housing sized to fit inside a battery tray of the vehicle, the housing including a docking port for removably receiving a rechargeable battery pack therein;
a pair of cables for electrically coupling the portable power source to battery leads of the vehicle;
a switching voltage regulator controller electrically coupled to the pair of cables and operable to transform battery power to output power for powering the one or more electrical control systems of the vehicle; and
a power source controller electrically coupled to the docking port and the switching voltage regulator, the power source controller operable to activate or deactivate the voltage controller in response to sensor signals received from a plurality of battery connection points on the docking port.

2. The portable power source of claim 1 further comprising a rechargeable battery pack with a plurality of battery terminals that are electrically coupled to the plurality of battery connection points when the rechargeable battery pack is installed in the docking port.

3. The portable power source of claim 2 wherein the rechargeable battery pack comprises a cordless power tool lithium-ion battery pack.

4. The portable power source of claim 1 wherein the housing is smaller than a 12 volt vehicle battery.

5. The portable power source of claim 1 wherein at least one of the plurality of battery connection points connects to a battery temperature sensor located inside the rechargeable battery pack when the rechargeable battery pack is installed in the docking port.

6. The portable power source of claim 1 further comprising a status indicator located on the housing and electrically coupled to the power source controller, the status indicator operable to indicate an operating condition, a low-level charge condition and a fault condition.

7. The portable power source of claim 1 wherein the docking port is operable to receive a 20-volt, 9.0 Amp-hour rechargeable battery pack and the switching voltage regulator controller is operable to deliver 12 volt output power.

8. The portable power source of claim 7 wherein the output power from the switching voltage regulator controller has a current in a range of 5 to 30 Amps.

9. The portable power source of claim 1 wherein the switching voltage regulator includes at least two switching voltage regulator controllers connected in parallel to one another.

10. The portable power source of claim 1 further comprising:
a current sensor electrically coupled to the power source controller and to the switching voltage regulator controller, wherein the power source controller monitors an output current of the switching voltage regulator controller in response to a signal received from the current sensor.

11. The portable power source of claim 1 further comprising:
an output voltage sensor electrically coupled to the power source controller and to the switching voltage regulator controller, wherein the power source controller monitors an output voltage of the switching voltage regulator controller in response to a signal received from the output voltage sensor.

12. The portable power source of claim 10 wherein the power source controller comprises a processor and non-transitory memory, the non-transitory memory having executable instructions stored thereon that, when executed by the processor, cause the power source controller to:
compare the output current to a predetermined current threshold; and
cause the switching voltage regulator controller to move to an off state to interrupt the output power from being delivered from the switching voltage regulator controller and to cause a status indicator to indicate a fault condition when the output current is greater than the predetermined current threshold.

13. The portable power source of claim 6 wherein the power source controller comprises a processor and non-transitory memory, the non-transitory memory having executable instructions stored thereon that, when executed by the processor, cause the power source controller to:
receive a sensor signal from a voltage sensor in the rechargeable battery pack, the sensor signal indicating a battery voltage of the rechargeable battery pack;
compare the battery voltage to a first predetermined voltage threshold; and
cause the switching voltage regulator controller to move to an on state to cause the output power to be delivered from the switching voltage regulator controller and to cause the status indicator to indicate the operating condition when the battery voltage is greater than the first predetermined voltage threshold, wherein the rechargeable battery pack has a sufficient charge level to uninterruptably provide the output power to the one or more electrical control systems of the vehicle for a programming time sufficient to program the one or more electrical control systems of the vehicle when the battery voltage is greater than the first predetermined voltage threshold.

14. A portable power source for providing temporary power to one or more electrical circuits within an automotive vehicle having a battery compartment sized to receive an engine cranking battery coupled to a pair of battery leads, the portable power source comprising:
a housing sized to fit within the battery compartment of the vehicle before the engine cranking battery is installed, the housing having output terminals for connection to the pair of battery leads;
a docking port disposed within the housing which provides a connection jack configured to mate with a rechargeable battery pack, the connection jack supplying at least the following: current from the rechargeable battery pack to a load, a temperature signal indicative of temperature of an inserted rechargeable battery pack and a charge signal indicative of state of charge of the inserted rechargeable battery pack;
a buck-boost converter circuit coupled to the output terminals and coupled to the connection jack to receive current from the inserted rechargeable battery pack, the buck-boost converter circuit being operative to adapt voltage and current supply characteristics of the inserted rechargeable battery pack to conform to voltage and current supply requirements of the one or more electrical circuits within the automotive vehicle; and
a microcontroller, powered by the inserted rechargeable battery pack and receptive of the temperature signal and the charge signal, the microcontroller being programmed to perform a regimen of diagnostic steps that include assessing the charge signal to determine if the inserted rechargeable battery pack has sufficient stored energy to supply the one or more electrical circuits within the automotive vehicle,
the microcontroller being coupled to the converter circuit to monitor current flow through the converter circuit and to supply a control signal to the converter circuit, the microcontroller being further programmed to employ the control signal to cause the converter circuit to interrupt current flow to the output terminals when monitored current flow and the temperature signal indicate that an excessive load has been placed on the inserted rechargeable battery pack.

15. The portable power source of claim 14 wherein the docking port is adapted to receive a rechargeable battery pack for a handheld cordless power tool.

16. The portable power source of claim 14 further comprising plural docking ports each disposed within the housing, each providing a connection jack configured to mate with a rechargeable battery pack.

17. The portable power source of claim 14 wherein the buck-boost converter circuit comprises an oscillator circuit and first and second synchronous converter circuits each coupled to the oscillator circuit for phase-locked operation and supplying current in parallel to the output terminals.

18. The portable power source of claim 14 wherein the buck-boost converter circuit comprises an oscillator circuit providing first and second oscillation signals of differing phase angles and first and second synchronous converter circuits each coupled to the oscillator circuit for phase-locked operation, the first synchronous converter circuit being phase locked to the first oscillation signal and the second synchronous converter being phase locked to the second oscillation signal.

19. The portable power source of claim 14 wherein the buck-boost converter circuit comprises an oscillator circuit providing first and second oscillation signals, respectively 180 degrees out of phase, and first and second synchronous converter circuits each coupled to the oscillator circuit for phase-locked operation, the first synchronous converter circuit being phase locked to the first oscillation signal and the second synchronous converter being phase locked to the second oscillation signal.

20. The portable power source of claim 14 further comprising an inserted rechargeable battery pack that produces a nominal voltage that is higher than the voltage requirements of the one or more electrical circuits within the automotive vehicle.
